(19) United States
(12) Patent Application Publication
(10) Pub. No.: US 2005/0258718 A1
(43) Pub. Date: Nov. 24, 2005

(54) Piezoceramic composition, piezoceramic body comprising said composition and a method for producing said composition and said body

(76) Inventors: Hermann Bodinger, Munchen (DE); Karl Lubitz, Ottobrunn (DE); Carsten Schuh, Baldham (DE)

Correspondence Address: YOUNG & THOMPSON, 745 SOUTH 23RD STREET, 2ND FLOOR, ARLINGTON, VA, 22202, US

(21) Appl. No.: 10/516,078

(22) PCT Filed: May 5, 2003
(86) PCT No.: PCT/DE03/01430

§ 371 Date: Jun. 30, 2005

(30) Foreign Application Priority Data
May 29, 2002 (DE) 102 23 987.8

(51) Int. Cl. H01L 41/187

(52) U.S. Cl. 310/358

(57) ABSTRACT

The invention relates to a piezoceramic composition with the general empirical formula Pb₁₋ₐRE_{b}ZrₓTi_{y}TR_{z}O₃, in which RE represents a rare-earth element, selected from a group comprising europium, gadolinium, lanthanum, neodymium, praseodymium, promethium and/or samarium, with a rare-earth element fraction b, TR represents at least one transition metal, selected from the group comprising chromium, iron and/or manganese, with a transition metal valency W<SB>TR</SB>and a transition metal fraction z and whereby the following interrelation is valid: z>b/(4−W<SB>TR</SB>). Homogenous PZT crystals with a maximum particle size are obtained even at low sintering temperatures by a non-stoichiometric dosing ratio of transition metal dosage to rare-earth element dosage. By varying the dosages, the piezoelectric characteristics of a PZT ceramic with said composition can be modified from those of a classic soft PZT to those of a classic hard PZT. The piezoceramic body is for example a monolithic, multi-layer piezoactuator, which can be used for multiple injections in the engine of a motor vehicle, as a result of a high d₃₃ coefficient and low internal dissipation in the high-level signal range.

The invention relates to a piezoceramic composition in the form of a lead zirconate titanate (Pb(Ti, Zr)O₃, PZT). In addition a piezoceramic body with the composition as well as a method of producing said composition and a method of producing said body are specified.

Lead zirconate titanate is a perovskite in which the A-sites of the perovskite are occupied by bivalent lead (Pb²,) and the B-sites of the perovskite by quadrivalent Zirconium (Zr⁴⁺) and quadrivalent titanium (Ti⁴⁺). To influence an electrical or piezoelectrical property such as permittivity, coupling factor or piezoelectric charging constant (for example d₃₃ coefficient) the composition is usually doped.

With what is known as a hard PZT, lower-value cations are incorporated at the A- or B-site of the perovskite. These cations are referred to as hardener doping. For a classical hard PZT the result of this type of doping is a relatively low dissipation factor tg δ and thereby a high mechanical quality factor Qₘ. The mechanical quality factor Qₘ amounts to 1000 for example. The high quality factor means that an internal dissipation which occurs with an electrical activation of a component with the hard PZT is low. However the d₃₃ coefficient of the hard PZT is relatively low. Hard PZT is thus not suitable for the type of application in which the greatest possible piezoelectrically-induced deflection is to be achieved. Hard PZT is thus rarely used in a piezoelectric actuator or in a piezoelectric bending converter.

With what is known as a soft PZT on the other hand, higher-value cations are built in at the A- or B-site of the perovskite. These cations are referred to a softener doping. This type of soft PZT is for example known from WO 97/40537, in which a small proportion of trivalent neodymium (Nd³⁺) occupies the A-site of the perovskitic PZT. The general molecular formula of the piezoceramic composition of the soft PZT is Pb_{0, 98}Nd_{0, 02}Zr_{0, 54}Ti_{0, 46}O₃. The softener doping means that a classic soft PZT is identified by a relatively high d₃₃ coefficient both in the low-value signal range (with field strengths of a few V/mm) and also in the high-value signal range (with field strengths of a few kV/mm). Soft PZT is thus suitable for use in actuators or bending converters. The disadvantage of this is that the dissipation factor tg δ is very high and thus a mechanical quality factor Qₘ is very low. The mechanical quality factor Qₘ amounts to 80 for example. In operation of a component with soft PZT a high internal dissipation therefore occurs, especially in the high-value signal area and this can lead to an undesired heating up of the component.

The object of the present invention is to specify a piezoceramic composition which exhibits both a high mechanical quality factor Qₘ and also a large d₃₃ coefficient.

The object is achieved by a piezoceramic composition with the general molecular formula Pb₁₋ₐRE_{b}ZrₓTi_{y}TR_{Z}O₃, in which RE is at least a selected rare earth element from the group europium, gadolinium, lanthanum, neodymium, praseodymium, promethium and/or samarium with a rare earth metal proportion b, TR is at least one transition metal selected from the group chromium, iron and/or manganese with a transition metal valency W_{TR} and a transition metal proportion z and the following relationship applies. z>b/(4−W_{TR})

To achieve the object a method for producing the piezoceramic composition is thus to be specified in which a maximum particle growth of the piezoceramic composition is determined for a specific sinter temperature.

In addition, to achieve the object, a piezoceramic body with the piezoceramic composition and a method for manufacturing the piezoceramic body will be specified. The method features the following steps: Provision of a green body with the piezoceramic composition and sintering of the green body to the piezoceramic body.

The rare earth metal RE and the transition metal TR are dopings of the PZT. In this case the PZT can be doped with a number of rare earth metals RE_{I} with corresponding rare earth metal proportions b_{I}. Thus the rare earth proportion b can represent a sum of a number of rare earth metal proportions b_{I}. Likewise the PZT can also be doped with a number of transition metals TRⱼ with corresponding transition metal proportions zⱼ. The transition metal proportion z can thus be a sum of the transition metal proportions zⱼ.

The possible rare earth metals (softener dopings) are selected so that, by comparison with Pb²⁺, they exhibit a similar ion radius. This leads to these rare earth metals primarily taking up the A-sites of the perovskitic PZT. The rare earth metals are preferably present as trivalent cations RE³⁺, so that the A-sites are partly occupied by higher dopings by comparison with Pb²⁺.

The possible transition metals (hardener dopings) are selected such that because of their ion radii, they primarily occupy the B-sites of the perovskitic PZTs. The rare earth metals preferably occur here with a valency of +2 or +3 so that the B-sites are primarily occupied by lower-valency dopings by comparison with Ti⁴⁺ and Zr⁴⁺.

Of particular importance, in addition to the explicit choice of the dopings, is the ratio of softener to hardener doping, expressed by the relationship of the transition metal proportion z, the deviation of the valency W_{TR} from +4 (the valency of titanium and zirconium at the B-sites) and of the rare earth metal proportion b. For the inventively important relationship softener and hardener doping are added to each other non-stoichiometrically. Softener and hardener dopings would be mixed stoichiometrically if the following relationship were to apply: z=b/(4−W_{TR}). Through the non-stoichiometric ratio a change in charge in the PZT brought about by the softener doping is overcompensated for by the hardener doping. With a hardener doping with trivalent iron (Fe³⁺) or trivalent chromium (Cr³⁺) for example more trivalent transition metal will be added than would be necessary as a result of the rare earth metal proportion and deviation of the valency of the rare earth metal (+3) from the valency of the lead (+2) (Z_{Fe}>b or Z_{cr}>b) . The same applies for a hardener doping with bivalent manganese (Mn²⁺) (Z_{Mn}>b/2). A mixed doping of bivalent manganese and trivalent iron for example produces the relationship for Z_{Fe}+2.z_{Mn}>b.

Surprisingly it has been shown that, for a non-stoichiometric ratio of the softener and the hardener doping to each other, PZT crystals are accessible which exhibit a relatively large particle size. In this case PZT crystals with a particle diameter of far in excess of 1 μm are accessible practically independent of the sinter temperature. The particle diameter of 1 μm is viewed as the critical minimum particle size for PZT, above which PZT exhibits good and thereby technically usable piezoelectric properties. The large particle sizes are possible by virtue of the fact that, based on the inventive relationship of the dopings, a maximum value particle growth of the PZT crystals can be set. With maximum particle growth almost no growth inhibitors occur as blank locations of the A-sites or B-sites or local doping complexes. With the inventive doping relationship almost every inhibitor to particle growth is removed. The dopings are built in both in the thermodynamic equilibrium and also in the charging equilibrium at a given sinter temperature homogenously into a growing PZT crystal. The result is that, under given sinter conditions (for example sinter temperature or sinter atmosphere) the largest possible PZT crystals are obtained. The range of maximum particle growth is to be defined empirically. The approximate relationship is as follows: (4.b)/(4−W_{TR})>z>b/(4−W_{TR}). For example, at a sinter temperature of 1050° C. the maximum particle growth of a piezoceramic composition with a neodymium proportion b_{Nd} of 2 mol % with a manganese proportion Z_{Mn}, of around 1.5 mol %. PZT crystals with a particle diameter of up to 13 μm are obtained. By contrast a doping with iron instead of manganese, with an iron proportion z_{Fe} of around 4 mol %, leads to maximum particle growth, with PZT crystals with a particle diameter of up to 10 μm being achievable. The result in the range of the maximum particle growth is relatively large PZT crystals.

The larger the PZT crystals the larger is the d₃₃ coefficient which can be achieved with these PZT crystals. Despite a relatively high proportion of hardener doping, a larger d₃₃-coefficient can be realized in this way than is typical for soft PZT. As a result of the relatively high proportion of hardener doping however it is possible by comparison with classical soft PZT to obtain a far dissipation factor tg δ. The dissipation factor tg δ and thereby the mechanical quality factor Qₘ which can be achieved can assume values which are typical of classical hard PZT.

The value of the mechanical quality factor Qₘ in particular is in a range from 50 up to and including 1800. It has been shown that the electrical and piezoelectrical properties of the composition can be tuned from those of a classic soft PZT through to the properties of a classic hard PZT. The type of transition metal plays an important role here. A doping with manganese leads for example to an increased particle growth and simultaneously a reduction in the dissipation factor tg δ. These effects also occur with low manganese proportions. Thus a large d₃₃ coefficient (for example 550 pm/V for an activation of 2 kV/mm) can be achieved at low internal dissipation.

A doping with iron results with only a slight deviation from the stoichiometric ratio of the rare earth metal and of the iron (Z_{Fe}=b) in an increased particle growth. But, unlike the doping with manganese, with the iron doping the dissipation factor tg δ only decreases with a greater deviation from the stoichiometric ratio. The deviation necessary for this amounts to 50% for example and lies within range of maximum particle size. This means that here, up to a ratio of the proportion of iron z_{Fe} to transition metal proportion b of 2 a larger d₃₃ coefficient can be achieved at a high internal loss. Thus the hardener doping with iron makes a composition with piezoelectric properties accessible which are typical of a classic soft PZT. With the maximum particle size for example a soft PZT is produced for which the high-level signal d₃₃ coefficient of around 950 pm/V at 1 kV/mm, despite hardener doping, is still above the known values for a classic soft PZT which only exhibits one softener doping.

The method for producing the piezoceramic composition comprises in a particular embodiment the following steps: Defining the rare earth metal proportion b, Defining the transition metal proportion z, sintering the piezoceramic composition at the sinter temperature, determining a particle size of the sintered piezoceramic composition and repeating the definition of the transition metal proportion z, of the sintering and of the determining of the particle size, with the transition metal proportion z being varied.

To set the desired relationship of the piezoceramic properties of a classic hard PZT to those of a classic soft PZT a mixed doping of manganese and iron is used especially. Alternatively a mixture of manganese and chrome can also be used. For the mixed doping of manganese and iron the transition metal iron with an iron proportion z_{Fe} and the transition metal manganese with a manganese proportion Z_{Mn} is used, so that the ratio to z_{Fe}+2.z_{Mn}, >b is produced and with the variation of the manganese proportion Z_{Mn} essentially the dissipation factor tg δ of the composition and with the variation of the iron proportion z_{Fe} essentially the maximum particle growth of the composition are set. Essentially this means that, with the transition metal proportions the dissipation factor tg δ of the iron doping and the particle growth are only slightly influenced by the manganese doping.

For example, for a given rare earth metal doping with rare earth metal proportion b a manganese proportion Z_{Mn} is explicitly selected which is lower than the manganese proportion which leads to the maximum particle size. Then sufficient iron is doped in until the point of maximum particle size is determined. A charge equalization in the PZT which is triggered by the non-stoichiometric relationship of softener and hardener dopings to each other is normally compensated for via empty positions. The result of the formal non-stoichiometric composition is however that with maximum particle growth no compensation via empty positions is necessary. At a given sinter temperature maximum particle growth takes place at an empirically determined ratio of transition metal proportion to rare earth metal proportion. With this ratio the cations are built into a practically defect-free perovskite by changing the valency and/or A/B-site equilibriums.

In a further embodiment the following further relationship applies: x+y+z=1. Zirconium, titanium and the transition metal are preferably built into the B-site of the perovskite. By changing the relationship between the zirconium proportion x and the titanium proportion y, the morphotropic phase boundary necessary for the piezoelectric properties of the PZT of tetragonal and rhomboidrical crystal structure can be set empirically from measured piezoelectric characteristics.

The piezoceramic composition can be present as a single piezoceramic material. The material can be a sintered or calcinated piezoceramic. In this case the material can be present in various crystalline phases. For the application of the PZT in a piezoceramic component a morphotropy of the PZT is for example of decisive importance. PZT is present with a specific ratio of the proportion x of the zirconium and of the proportion of the titanium in a tetragonal and rhomboidrical crystal structure (morphotropy).

The piezoceramic material is for example an element of a sintered piezoceramic body. The piezoceramic material is a monolithic PZT ceramic.

A density of the piezoceramic material in the piezoceramic body preferably amounts to more than 96%.

In particular the piezoceramic material is a powder which is used for producing a piezoceramic body with the composition. The powder consists for example of just powder particles with the piezoceramic composition. It is however also conceivable for the powder to be present as a powder mixture of various oxides which produce the composition with the general (nominal) molecular formula. For example the powder mixture consists of (1-a) lead oxide (PbO), b rare earth metal oxide (RE₂O₃), x zirconium oxide (ZrO₂), y titanium oxide (TiO₂) and Z_{Mn}, manganese oxide (MnO). A component of the powder mixture can also be a mixed oxide such as zirconium titanate ((ZrₓTi₁₋ₓ)O₂) which is accessible through a hydrothermal precipitation for example. The lead component (1-a) is set in this case such that before the beginning of a sintering a percentage excess of lead oxide is present. This excess of lead oxide advantageously leads to a compression of the powder at a relatively low temperature.

The powder is produced from the powder particles with the piezoceramic composition for example starting with the described powder mixture in a so-called mixed-oxide process. For the production of the powder chemical manufacturing methods such as the hydrothermal or sol-gel method is advantageous, which inherently lead to homogeneous powder particles. By explicitly selecting the dopings based on the ion radii however, even when using the low-cost mixed-oxide process, it is still possible to produce a homogeneous doping inclusion of the rare earth metal and transition metal from particle to particle.

In a particular embodiment the rare earth metal proportion is selected from a range of 0.2 mol % to 3 mol %. The low rare earth metal proportion has a positive influence on the particle size. The lower the rare earth metal proportion the greater the particle sizes that can be achieved on sintering.

In a further embodiment the overall sum of rare earth metal proportions and transition metal proportions is less than 6 mol %. It is advantageous if in addition to a low rare earth metal proportion the transition metal proportion is also low. This also contributes to the fact that, even at a low sinter temperature, PZT crystals are obtained which have at least the critical minimum size of 1 μm. Furthermore a low doping proportion means that the Curie temperature T_{c} of the piezoceramic composition is not reduced too greatly. In particular the ceramic composition has a Curie temperature T_{c} which is above 280° C. The relatively high Curie temperature leads to the piezoceramic composition being used at a higher temperature For example a component with the piezoceramic composition can be used in the engine compartment of a motor vehicle.

As well as the level of proportions of rare earth metal and transition metal it is also especially advantageous for the number of different dopings to be as low as possible. Advantageously the piezoceramic composition features a maximum of three different dopings. In particular RE here is a single rare earth metal and TR is selected from at most two transition metals or TR is a single transition metal and RE is selected from at most two rare earth metals. The lower number of different dopings means that the dopings can be incorporated very homogeneously from particle to particle and within each of the particles. This contributes to a very good particle growth.

In accordance with a further embodiment of the piezoceramic body with the piezoceramic composition, the body features at least one metallization selected from the group silver, copper and/or palladium. The piezoceramic body is manufactured in particular by joint sintering of the piezoceramic composition and the metallization (cofiring). The metallization can be an alloy of silver and palladium in this case. In particular in this embodiment the proportion of palladium is selected so as to range from 0% up to and including 30%. In this case 0%, means that almost no palladium is present. Preferably the proportion of palladium is a maximum of 5%. The fact that with the aid of the piezoceramic composition a PZT ceramic with large PZT crystals and a high ceramic density is also accessible at relatively low sinter temperatures enables metallizations with lower melt temperatures such as silver or copper to be sintered together with the ceramic material. In particular by sintering the piezoceramic body in a reducing sinter atmosphere it is possible to have a low-cost copper as metallization. The option of using silver or a silver or silver palladium alloy with a low proportion of palladium as metallization means that the costs for manufacturing these components are also greatly reduced.

A further advantage as regards the piezoceramic composition is that the likelihood of the occurrence of an interaction of the metallization and the piezoceramic materials on sintering is reduced to a minimum. In the piezoceramic material the number of empty positions of the A- and B-sites is minimal. During joint sintering there is only a minimum number of free positions available for a reaction between the metallization and the piezoceramic material. This reaction consists for example of a diffusion of silver or copper from the metallization into the empty positions. A suppression of this reaction allows the interaction of the PZT with the metallization to be very easily controlled.

In a special embodiment the piezoceramic body exhibits a monolithic multilayer construction in which piezoceramic layers with the piezoceramic composition and electrode layers with metallization are arranged alternately above one another. For example the piezoceramic body is a multilayer monolithic piezoactuator.

In particular the piezoceramic body is a component selected from the group actuator, bending converter, motor and/or transformer. The actuator can for example be used for active vibration damping or for multiple injection in the motor vehicle. With multiple injection the actuator is activated several times per revolution of the engine of the motor vehicle Were a classical soft PZT to be used, because of the high internal dissipation and the associated self-heating, this could lead to the component overheating. With the piezoceramic composition this problem can be surmounted.

To produce the piezoceramic body a green body is provided in particular with a metallization which is selected from the group silver, copper and/or palladium. The green body consists for example of green foils stacked one above the other, provided with corresponding metallization. This green body is transferred to a piezoceramic body in monolithic multilayer construction in a joint sinter process.

To produce the piezoceramic body the sintering is conducted in particular in an oxidizing or reducing sinter atmosphere. By contrast with an oxidizing sinter atmosphere, almost no oxygen is present in a reducing sinter atmosphere. An oxygen partial pressure amounts to less than. 1.10⁻² mbar and preferably less than 1.10⁻³ mbar. This for example allows internal electrodes made of copper to be integrated into a multilayer piezoactuator in a joint sinter process of the piezoceramic composition and the copper metallization.

Preferably in this case a sinter temperature ranging from 900° C. up to and including 1100° C. is selected. Despite the low sinter temperature a ceramic body with a high density is accessible. The ceramic density amounts to 96% for example. The resulting piezoceramic body consists of relatively large PZT crystals. The PZT crystals obtained on sintering exhibit, even at a low sinter temperature of 950° C. to 1100° C. for PZT, a particle diameter of much more than 1 μm.

To ensure PZT crystals with a specific minimum size a green body with a plurality of particle growth seeds can be used in this case. These particle growth seeds especially feature the piezoceramic composition. The particle growth seeds can for example be produced from monolithic PZT of equivalent composition sintered at high temperature by reduction (for example grinding) with particle diameters of 1 μm and the powder, before the green body is produced, for example through foil drawing, added in a number which corresponds to the number of the PZT crystals after the sintering of the green body to the piezoceramic body.

In summary the invention produces the following major advantages:
The piezoceramic composition is selected so that a piezoceramic with very large particle size is also accessible at low sinter temperature. A final density of the piezoceramic is very high in this case (over 96%).
The piezoceramic with the piezoceramic composition stands out by virtue of high homogeneity from particle to particle and within each particle. This is especially achieved with a pure chromium, iron or manganese doping. The results are outstanding low-level and high-level signal values for hard and/or soft PZTs.
Through the low sinter temperature a metallization with low melt temperature can be used to produce a monolithic ceramic body by a joint sintering of the metallization and the ceramic composition.
By focusing on the maximum particle size an interaction between the ceramic and the metallization is reduced to a minimum. This allows defined piezoelectric characteristic values to be set and the production of the piezoceramic to be undertaken in a stable and reproducible way.
Through mixed doping of two hardener dopings a piezoceramic component, especially a multilayer component with any given properties between optimum soft PZT and optimum hard PZT is accessible.

The invention will be explained in greater detail below using a number of examples and the associated Figures. The Figures are schematic and do not represent true-to-scale illustrations

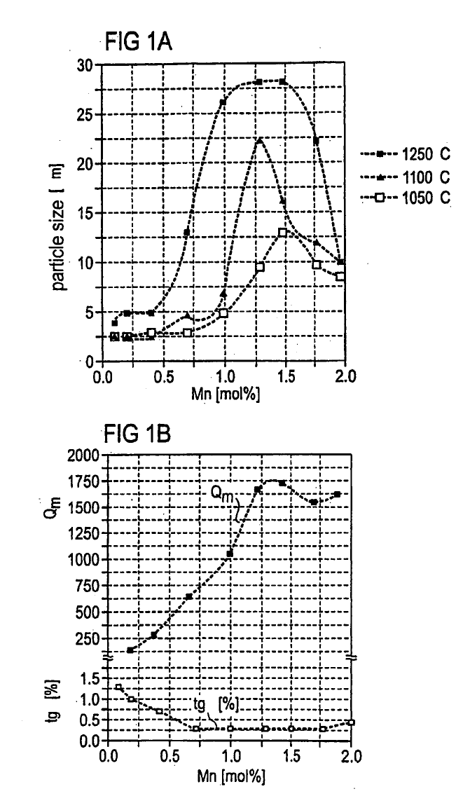

FIG. 1a shows the dependence of the particle size on the transition metal proportion of a first exemplary embodiment.

FIG. 1b shows the dependence of the dissipation factor tg δ and the mechanical quality factor Qₘ on the transition metal proportion of the first exemplary embodiment.

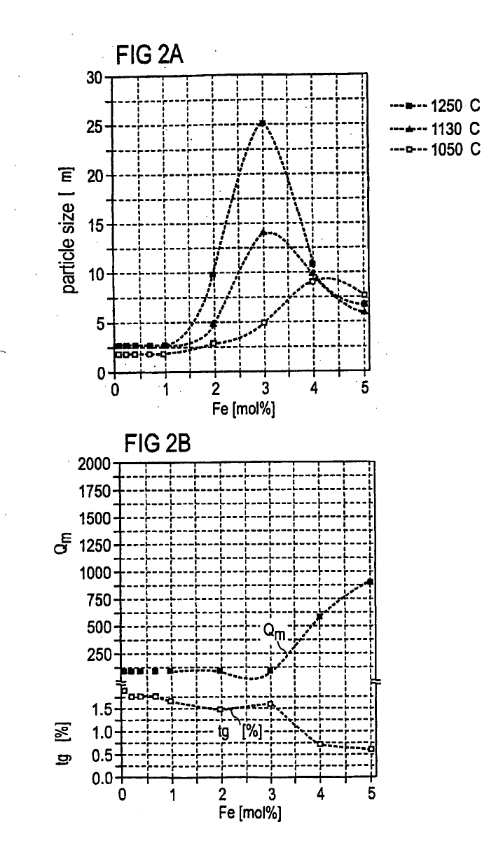

FIG. 2a shows the dependence of the particle size on the transition metal proportion of a second exemplary embodiment.

FIG. 2b shows the dependence of the dissipation factor tg δ and the mechanical quality factor Qₘ on the transition metal proportion of the second exemplary embodiment.

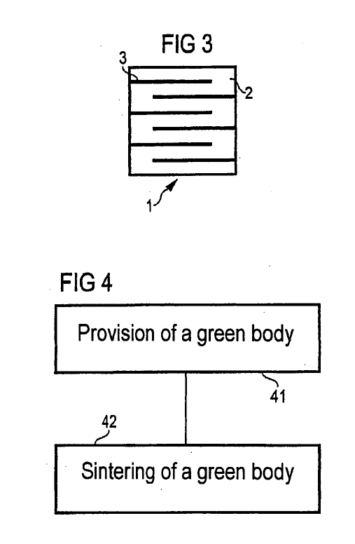

FIG. 3 shows a piezoceramic body with the piezoceramic composition.

FIG. 4 shows a method for producing the piezoceramic body.

### EXEMPLARY EMBODIMENT 1

The piezoceramic composition features the following general formula: Pb₁₋ₐNd_{0, 02}ZrₓTi_{y}Mn_{z}O₃. FIG. 1a specifies the composition of manganese proportion Z_{Mn}, in mol % and of sinter temperature depending on the particle size.

Even at a low doping with manganese the particle size increases. PZT crystals with maximum particle size are obtained for a proportion of manganese which, at a sinter temperature of 1100° C., is around 1.3 mol %, that is above b_{Nd}/2 (1 mol %). The non-symmetrical doping of the rare earth metal neodymium, which is contained in the compound with a neodymium proportion b_{Nd} of 2 mol % and of the transition metal manganese, leads to maximum particle size.

FIG. 1b shows the dependence of the dissipation factor tg δ and the mechanical quality factor Qₘ on the manganese proportion Z_{Mn}, of the composition sintered at 1250° C. Even with a low doping with manganese the dissipation factor tg δ falls drastically. The mechanical quality factor Qₘ thereby rises. The resulting piezoceramic is outstanding by virtue of its low internal losses.

The minimum particle size necessary for a PZT ceramic is also achieved at a sinter temperature needed for a metallization of copper or silver of less than 950° C.

### EXEMPLARY EMBODIMENT 2

The piezoceramic composition features the following general formula: Pb₁₋ₐNd_{0, 02}ZrₓTi_{y}Fe_{z}O₃. FIG. 2a specifies the composition of iron proportion Z_{Fe}, in mol % and of sinter temperature, depending on the particle size.

PZT crystals with maximum particle size are obtained for a proportion of iron which, at a sinter temperature of 1130° C., is around 3 mol % that is above b_{Nd}(2 mol %). The non-symmetrical doping of the rare earth metal neodymium and of the transition metal iron leads to maximum particle size.

FIG. 2b shows the associated dependence of the dissipation factor tg δ and of the mechanical quality factor Qₘ on the proportion of iron. Even with a greater deviation from the stoichiometric ratio of the proportion of neodymium and of iron(Z_{Fe>}3 mol %) the dissipation factor tg δ falls considerably.

It is also true here that the minimum particle size necessary for a PZT ceramic is also achieved at a sinter temperature necessary for a metallization from copper or silver of less than 950° C.

The composition in accordance with exemplary embodiment 1 is used to produce a piezoceramic body 1 (FIG. 3). The piezoceramic body is a monolithic multilayer piezoactuator, in which ceramic layers 2 with the piezoceramic composition and internal electrodes 3 are arranged alternating above one another. The internal electrodes 3 are made of a metallization of a silver palladium alloy containing palladium in a proportion of 5 weight.%.

To produce the piezoactuator green foils are provided with the piezoceramic composition (step 41, FIG. 4). To do this a powder is mixed with the composition with an organic binder. The ceramic green foils are molded from the slip obtained in this way. The green foils are printed with a paste with the metallization, stacked above one another, debindered and sintered to the piezoactuator under an oxidized atmosphere (step 42, FIG. 4). The piezoactuator is outstanding by virtue of a very good high-level signal d₃₃ coefficient at very low internal losses. The use of the piezoactuator by the electrical actuation system does not result in undesired self-heating. The piezoactuator is thus also suitable for using multiple injection systems in the engine of a motor vehicle.

1. Piezoceramic composition with the general molecular formula Pb₁₋ₐRE_{b}ZrₓTi_{y}TR₂O₃, in which
RE is at least one rare earth metal selected from the group europium, gadolinium, lanthanum, neodymium, praseodymium, promethium and/or samarium with a rare earth metal proportion b,
TR is at least one transition metal selected from the group chromium, iron and/or manganese with a transition metal valency W_{TR} and a transition metal proportion z and
The following relationship applies: z>b/(4−W_{TR}).

2. Piezoceramic composition in which the rare earth metal proportion is selected from a range of 0.2 mol % to 3 mol %.

3. Piezoceramic composition in accordance with claim 1, in which a sum of the rare earth metal proportion and of the transition metal proportion is less than 6 mol %.

4. Piezoceramic composition in accordance with claim 1, in which the RE is a single rare earth metal and TR is selected from at most two transition metals or TR is a single transition metal and RE is selected from at most two rare earth metals.

5. Piezoceramic composition in accordance with claim 1, with a value for a mechanical quality factor Qₘ which is selected from a range 50 up to and including 1800.

6. Piezoceramic composition in accordance with claim 1, with a Curie-temperature T_{c} lying above 280° C.

7. Method for producing a piezoceramic composition in accordance with one claim 1, in which a maximum particle growth of the piezoceramic composition is determined at a specific sinter temperature.

8. Method in accordance with claim 7, where the following steps are performed:
a) Definition of the rare earth metal proportion b,
b) Definition of the transition metal proportion z,
c) Sintering of the piezoceramic composition at the sinter temperature,
d) Determining a particle size of the sintered piezoceramic composition and
e) Repeating steps b) to d), with the transition metal proportion z being varied.

9. Method in accordance with claim 7, with the transition metal iron with an iron proportion zFe and the transition metal manganese with a manganese proportion Z_{Mn} being used, so that the relationship to z_{Fe}+2·Z_{Mn},>b is produced and with the variation of the manganese proportion Z_{Mn}, essentially the dissipation factor tg δ of the composition and with the variation of the iron proportion z_{Fe}, essentially the maximum value particle growth of the composition are set.

10. Piezoceramic body with a piezoceramic composition in accordance with claim 1.

11. Piezoceramic body in accordance with claim 10, featuring a metallization selected from at least one of the group silver, copper and/or palladium.

12. Piezoceramic body in accordance with claim 11, in which a proportion of palladium is selected ranging from 0% up to an including 30%.

13. Piezoceramic body in accordance with claim 12, in which the proportion of palladium amounts to a maximum of 5%.

14. Piezoceramic body in accordance with claim 10, featuring a monolithic multilayer construction in which piezoceramic layers with the piezoceramic composition and electrode layers with the metallization are arranged alternating above one another.

15. Piezoceramic body in accordance with claim 10, which is a component selected from the group actuator, bending converter, motor and/or transformer.

16. Method for producing a piezoceramic body, with the steps:
f) Provision of a green body with a piezoceramic composition in accordance with claim 1 and
g) Sintering of the green body to the piezoceramic body.

17. Method in accordance with claim 16, where a green body is provided with a metallization which is selected from the group silver, copper and/or palladium.

18. Method in accordance with claim 16 [[or 17]], where the sintering is undertaken in an oxidizing or reducing sinter atmosphere.

19. Method in accordance with one claim 16, with a sinter temperature ranging from 900° C. to 1100° C. inclusive being selected for sintering.

20. Method in accordance with one claim 16, with a green body with a plurality of particle growth seeds being used with the piezoceramic composition.
